(19) United States
(12) Patent Application Publication
(10) Pub. No.: US 2017/0162474 A1
(43) Pub. Date: Jun. 8, 2017

(54) COOLING MODULE AND ELECTRONIC DEVICE

(71) Applicant: SIEMENS AKTIENGESELLSCHAFT, München (DE)

(72) Inventors: Jakob Löschke, München (DE); Randolf Mock, Hohenbrunn (DE)

(21) Appl. No.: 15/325,750

(22) PCT Filed: Mar. 24, 2015
(86) PCT No.: PCT/EP2015/056295

§ 371 Date: Jan. 12, 2017

(30) Foreign Application Priority Data
Jul. 16, 2014 (DE) 10 2014 213 851.5

(51) Int. Cl. H01L 23/467; H05K 7/20; F28F 13/10

(52) U.S. Cl. CPC H01L 23/467; F28F 13/10; H05K 7/20909

(57) ABSTRACT

The cooling module includes a heat sink for cooling a power component of an ultrasonic source and a resonance tube arranged between the ultrasonic source and the heat sink. The cooling module is designed to guide a stream of air flowing through the resonance tube in a circumferential predefined direction (e.g., in a direction along an inner circumference of the resonance tube). The electronic device includes a power component and a heat sink provided for cooling, the heat sink of the cooling module being designed and arranged for cooling the power component.

The present patent document is a §371 nationalization of PCT Application Serial Number PCT/EP2015/056295, filed Mar. 24, 2015, designating the United States, which is hereby incorporated by reference, and this patent document also claims the benefit of DE 10 2014 213 851.5, filed Jul. 16, 2014, which is also hereby incorporated by reference.

### TECHNICAL FIELD

The disclosure relates to a cooling module and to an electronic device.

### BACKGROUND

The effect of ultrasonic wind has been known for approximately 180 years. This ultrasonic wind may be used to cool electronic components and assemblies, in particular power components such as high-power Light Emitting Diodes (LEDs), for example. However, the ultrasonic wind alone may not be sufficient to cool electronic components and assemblies such as power components, for example. Instead, it is often necessary to assist and to amplify the cooling action of the ultrasonic wind by further phenomena. For example, WO 2013/150071 A2 discloses a resonant method operating in accordance with the principle of a stopped organ pipe and amplifies the cooling effect of the ultrasonic wind by almost one order of magnitude. Nevertheless, it is still desirable to further amplify the cooling action of the ultrasonic wind.

### SUMMARY AND DESCRIPTION

The scope of the present disclosure is defined solely by the appended claims and is not affected to any degree by the statements within this summary. The present embodiments may obviate one or more of the drawbacks or limitations in the related art.

The object of the disclosure is therefore to specify a cooling module that is improved in comparison to the prior art and which allows, in particular, an improved cooling action of the ultrasonic wind. A further object of the disclosure is to provide an improved electronic device having the improved cooling module.

These objects of the disclosure are achieved by a cooling module and also by an electronic device.

The cooling module has a heat sink for cooling a power component, an ultrasound source, and also a resonance tube arranged between the ultrasound source and the heat sink. The resonance tube is designed to guide the air stream, which flows through the resonance tube, e.g., at least in a circumferential predefined direction (e.g., in a direction along an inner circumference of the resonance tube). Therefore, the formation of the acoustic wind is considerably supported in the cooling module. Owing to the circumferential guidance of the air stream, the air stream is swirled to a certain extent. This swirling provides additional eddy formation at the interface to the heat sink, so that an insulating air layer, which may form at the interface between the heat sink and the air, is reduced. The cooling action of the cooling module is consequently improved in comparison to the prior art.

Otherwise, the cooling module is expediently dimensioned in the manner described in WO 2013/150071 A2. In particular, the resonance tube, unless described differently in this description, is dimensioned and arranged in the manner described in WO 2013/150071 A2.

In this case, it is particularly expediently provided that the ultrasound source is designed to generate ultrasound waves of a prespecified wavelength and the distance between the ultrasound source and the heat sink corresponds to an integer multiple of a quarter of the wavelength. In this way, the cooling effect produced by the ultrasonic wind may be considerably amplified on account of developing resonances in the resonance tube.

In the case of the cooling module, the average diameter of the resonance tube may correspond substantially to the wavelength. In this case, the average diameter of the resonance tube refers to the diameter of a circle having the same surface area compared with the inside cross section of the resonance tube. The diameter of the resonance tube corresponding substantially to the wavelength may also differ from the wavelength to a slight extent, e.g., by at most one eighth of the wavelength, by at most one sixteenth of the wavelength, or by at most one thirty-second of the wavelength. Resonances may be excited in the resonance tube in a particularly simple manner in this case.

In an advantageous development of the cooling module, the cooling module has at least one flow guide within the resonance tube, e.g., arranged over the inner circumference of the resonance tube. Therefore, the resonance tube may expediently be of circular-cylindrical design, wherein the flow guide is designed in the form of a bead or with a sharp edge.

The at least one flow guide may be of helical design, e.g., in the form of a helical sheet-metal strip. An air flow with swirling is also generated.

In certain embodiments, the resonance tube may have at least one aperture running radially and circumferentially in the case of the cooling module. Owing to the at least also circumferential profile of the aperture, air flowing into the resonance tube through the aperture is likewise moved (e.g., swirled) in the circumferential direction.

The at least one aperture expediently forms a slot, (e.g., a longitudinal slot), in an advantageous development of the cooling module. In this development as a slot or longitudinal slot, there may be a high inflow rate of air into the resonance tube, so that the swirling is as intense as possible.

The at least one longitudinal slot extends over more than 50%, over more than 75%, or more than 90%, of the longitudinal dimension of the resonance tube.

In certain embodiments, the resonance tube may have an inside cross-sectional contour in the form of a polygon. The corners of this polygon revolve circumferentially as progress is made along the longitudinal extent of the resonance tube. The resonance tube of the cooling module also has a circumferential guide profile, which circumferentially guides air flowing through the resonance tube. Accordingly, air flowing through the resonance tube is also swirled in the circumferential direction.

In certain embodiments, the corners of the polygon describe straight inner edges as progress may be made along the longitudinal extent of the resonance tube. The resonance tube may be manufactured in a very simple manner in this development of the cooling module.

The electronic device has a power component and a cooling module, which is provided for cooling purposes, as described above. The heat sink of the cooling module is designed and arranged to cool the power component. The arrangement expediently corresponds, in principle, to that of the exemplary embodiments of document WO 2013/150071 A2.

### BRIEF DESCRIPTION OF THE DRAWINGS

The disclosure will be explained in greater detail below with reference to exemplary embodiments illustrated in the drawings, in which:

FIG. 1 schematically depicts an example of a longitudinal section through a cooling module.

FIG. 2A schematically depicts a perspective illustration of a resonance tube of the cooling module in accordance with FIG. 1.

FIG. 2B depicts a cross section through the resonance tube in accordance with FIG. 2A.

FIG. 3A schematically depicts a perspective illustration of a further exemplary embodiment of a resonance tube of the cooling module in accordance with FIG. 1.

FIG. 3B schematically depicts a cross section through the resonance tube according to FIG. 3A,

FIG. 4 schematically depicts a perspective illustration of a further exemplary embodiment of a resonance tube of the cooling module in accordance with FIG. 1.

FIG. 5 schematically depicts an example a longitudinal section through an electronic device.

### DETAILED DESCRIPTION

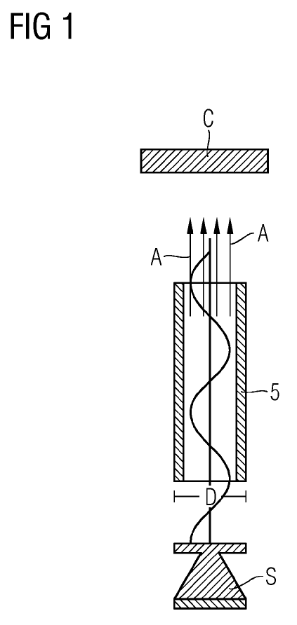

The cooling module illustrated in FIG. 1 has a heat sink C for cooling a power component, an ultrasound source in the form of a sonotrode S, and a resonance tube 5 which is arranged between the sonotrode S and the heat sink C. As described below, the resonance tube 5 is designed to guide an air stream A, which flows through the resonance tube 5, e.g., in a circumferential predefined direction (e.g., in a direction along an inner circumference of the resonance tube). On account of this circumferential guidance of the air stream A, the air stream A is swirled to a certain extent. This swirling provides additional eddy formation at the interface to the heat sink C, so that an insulating air layer, which may form at the heat sink C, is reduced.

The sonotrode S is designed to generate ultrasonic waves of a prespecified wavelength. The distance between the sonotrode S and the heat sink C corresponds to an integer multiple of a quarter of this wavelength. The average diameter D of the resonance tube 5 is one wavelength.

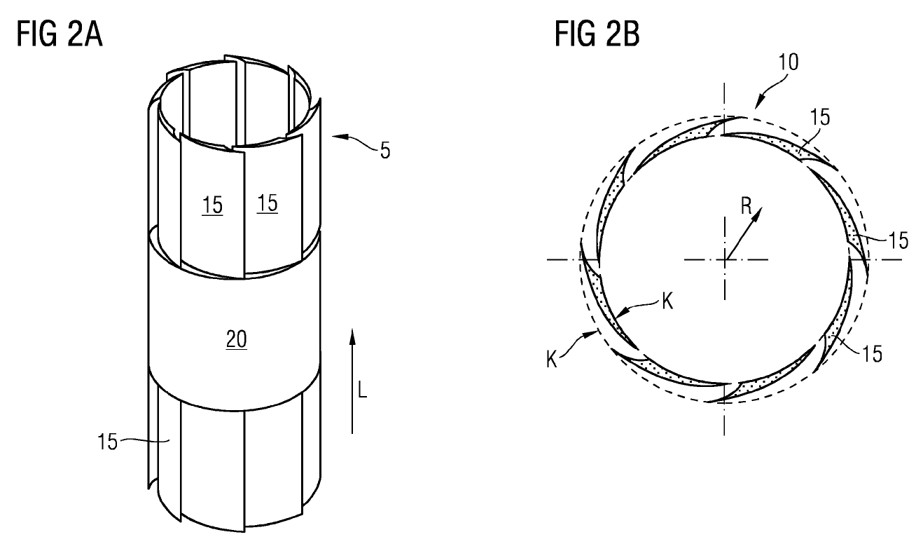

The resonance tube 5, illustrated in detail in FIGS. 2A and 2B, of the cooling module shown in FIG. 1 has a cross section of which the contours respectively coincide radially on the inside and radially on the outside with the circular internal or external contour of a ring K. The resonance tube 5 has apertures 10 extending in the longitudinal direction L of the resonance tube 5 and which occupy the entire longitudinal extent of the resonance tube 5. In this way, the apertures 10 form slots, in this case longitudinal slots. The apertures run along from 45° in the circumferential direction of the resonance tube 5. Along this 45°, the apertures 10 extend from the outer circumference of the resonance tube 5 to the inner circumference. The apertures 10 narrow toward the inside in the manner of nozzles, that is to say the apertures 10 narrow radially inward in the plane spanned by the circumferential and radial direction R as progress is made through the apertures 10.

On account of the longitudinal extent of the apertures 10 along the entire longitudinal dimension of the resonance tube 5, the resonance tube 5 is broken down into individual longitudinal slats 15 as illustrated in FIGS. 2A and 2B. These longitudinal slats are held together by a circumferential sleeve 20 to which the longitudinal slats are fastened.

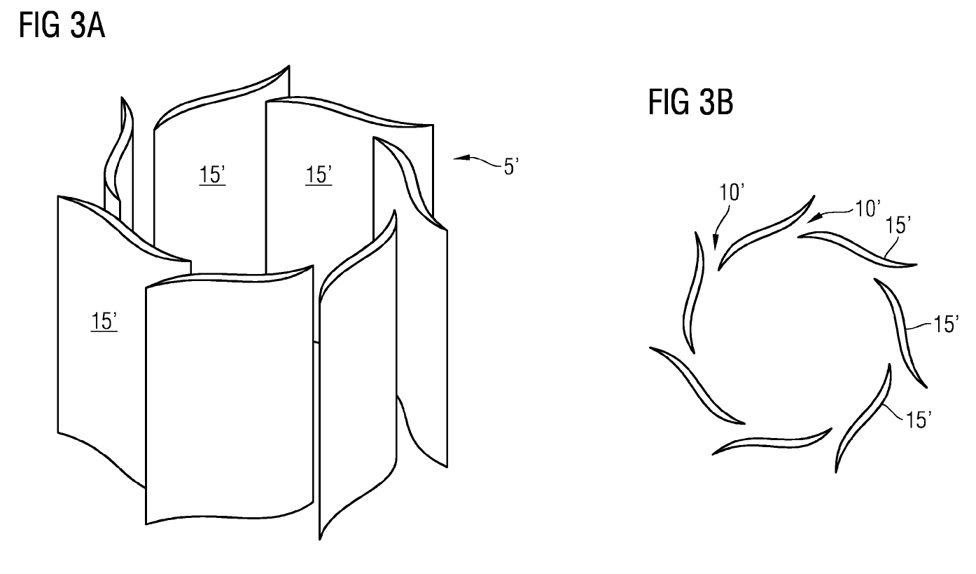

In a further exemplary embodiment of the cooling module, resonance tube 5′ illustrated in FIGS. 3A and 3B replaces the resonance tube 5 of the cooling module illustrated in FIG. 1. The resonance tube 5′ is, in principle, of similar construction to that according to FIGS. 2A and 2B. However, in contrast to the resonance tube 5 explained above, the resonance tube 5′ does not have a cross section of which the inner and outer contours coincide radially on the inside and on the outside with those of a ring K, but rather the longitudinal slats 15′ of the resonance tube 5′ have, in contrast thereto, an undulating cross section. Similarly to the above-described exemplary embodiment, slots that narrow in the form of nozzles into the interior of the resonance tube 5′ and extend along the entire longitudinal extent of the resonance tube 5′ are formed by the undulating cross section.

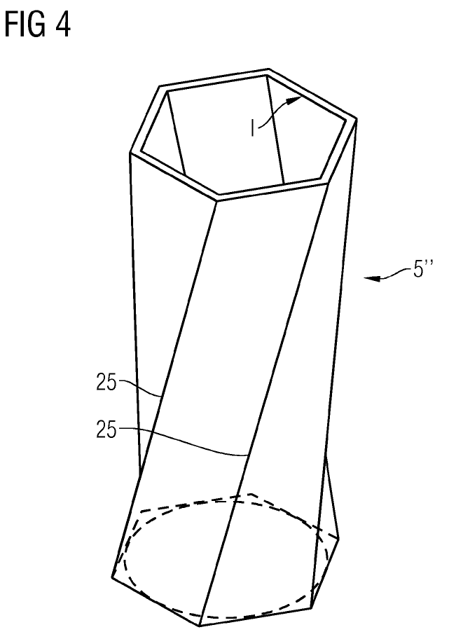

In a further exemplary embodiment of the cooling module, the resonance tube 5″ illustrated in FIG. 4 replaces the resonance tubes 5, 5′ of the above-described cooling modules. The resonance tube 5″ has an inside cross-sectional contour I of a polygon, of a hexagon in the illustrated exemplary embodiment. The corners of this hexagon revolve circumferentially as progress is made along the longitudinal extent of the resonance tube 5″, therefore in the longitudinal direction L.

The corners of the hexagon revolve in such a way that the corners describe straight inner edges 25 as progress is made along the longitudinal extent of the resonance tube 5″. A twisted hexagonal tube is formed to a certain extent in this way, the twisted hexagonal tube consequently forcing the air stream, which flows through the resonance tube 5″, to swirl circumferentially. In further exemplary embodiments, not shown separately, the polygon is a regular polygon with a different number of corners.

In a further exemplary embodiment of the cooling module, the resonance tube is of circular-cylindrical construction and has a helical, bead-like, or sharp-edged structure running within or on the wall, e.g., in the form of sheet-metal strips extending in a helical manner.

Further exemplary embodiments of cooling modules may each be found in the exemplary embodiments of the cooling apparatuses of document WO 2013/150071 A2, in which the circular-cylindrical resonance tubes described there are respectively replaced by the resonance tubes with a configuration as described above.

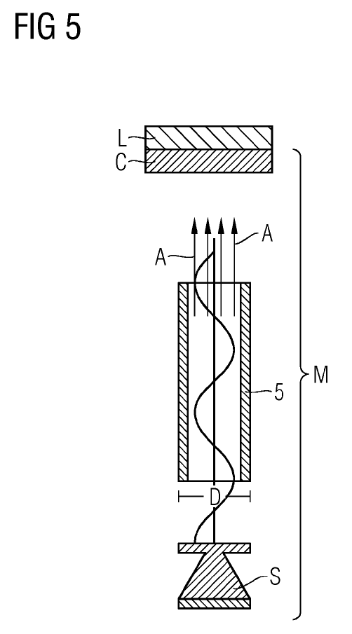

The electronic device illustrated in FIG. 5 has a power component L and a cooling module M provided for cooling purposes, as described above. The heat sink C of the cooling module M is of flat design for the purpose of cooling the power component L and is arranged such that it bears flat against the power component L.

Although the disclosure is illustrated more closely and described in detail by way of the exemplary embodiments, the disclosure is not restricted to the disclosed examples and other variations may be derived therefrom by a person skilled in the art without departing from the scope of protection of the disclosure. It is therefore intended that the foregoing description be regarded as illustrative rather than limiting, and that it be understood that all equivalents and/or combinations of embodiments are intended to be included in this description.

It is to be understood that the elements and features recited in the appended claims may be combined in different ways to produce new claims that likewise fall within the scope of the present disclosure. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

1. A cooling module comprising:
a heat sink configured to cool a power component;
an ultrasound source; and
a resonance tube arranged between the ultrasound source and the heat sink,
wherein the resonance tube is configured to guide an air stream flowing through the resonance tube at least in a direction along an inner circumference of the resonance tube.

2. The cooling module of claim 1, further comprising:
at least one flow guide within the resonance tube.

3. The cooling module of claim 2, wherein the at least one flow guide comprises a helical design.

4. The cooling module of claim 1, wherein the resonance tube has at least one aperture running radially and circumferentially.

5. The cooling module of claim 4, wherein the at least one aperture provides a longitudinal slot.

6. The cooling module of claim 5, wherein the at least one longitudinal slot extends over more than 50% of a longitudinal dimension of the resonance tube.

7. The cooling module of claim 1, wherein the resonance tube has an inside cross-sectional contour in a form of a polygon, and
wherein corners of the polygon revolve circumferentially as progress is made along a longitudinal extent of the resonance tube.

8. The cooling module of claim 7, wherein the corners of the polygon describe straight inner edges as progress is made along the longitudinal extent of the resonance tube.

9. An electronic device comprising:
a power component; and
a cooling module having a heat sink, an ultrasound source, and a resonance tube arranged between the ultrasound source and the heat sink, wherein the resonance tube is configured to guide an air stream flowing through the resonance tube at least in a direction along an inner circumference of the resonance tube,
wherein the heat sink of the cooling module is configured to cool the power component.

10. The cooling module of claim 2, wherein the at least one flow guide is arranged over the inner circumference of the resonance tube.

11. The cooling module of claim 5, wherein the at least one longitudinal slot extends over more than 75% of a longitudinal dimension of the resonance tube.

12. The cooling module of claim 5, wherein the at least one longitudinal slot extends over more than 90% of a longitudinal dimension of the resonance tube.

13. The cooling module of claim 2, wherein the resonance tube has at least one aperture running radially and circumferentially.

14. The cooling module of claim 3, wherein the resonance tube has at least one aperture running radially and circumferentially.

15. The cooling module of claim 2, wherein the resonance tube has an inside cross-sectional contour in a form of a polygon, and
wherein corners of the polygon revolve circumferentially as progress is made along a longitudinal extent of the resonance tube.

16. The cooling module of claim 3, wherein the resonance tube has an inside cross-sectional contour in a form of a polygon, and
wherein corners of the polygon revolve circumferentially as progress is made along a longitudinal extent of the resonance tube.
